(19) United States
(12) Patent Application Publication
(10) Pub. No.: US 2013/0069502 A1
(43) Pub. Date: Mar. 21, 2013

(54) HANDHELD MOBILE DEVICE CASING AND MOLDING METHOD OF THE SAME

(71) Applicants: Weilin Hu, Beijing (CN); Wei Zheng, Beijing (CN)

(72) Inventors: Weilin Hu, Beijing (CN); Wei Zheng, Beijing (CN)

(73) Assignee: BALDA SOLUTION (BEIJING) LTD., Beijing (CN)

(21) Appl. No.: 13/698,653

(22) PCT Filed: Jul. 9, 2010
(86) PCT No.: PCT/CN10/75090

§ 371 Date: Nov. 18, 2012

(30) Foreign Application Priority Data
May 18, 2010 (CN) 201010175317.0

(51) Int. Cl. H05K 5/03; H05K 13/00

(52) U.S. Cl. CPC H05K 5/03; H05K 13/00
USPC 312/223.1; 264/279

(57) ABSTRACT

A handheld mobile device casing and a molding method of the same includes manufacturing a glass part and a supporting part. The glass part is used as a sight window on the handheld mobile device casing, and the supporting part is used to support the glass part. The glass part is placed on the supporting part in a staggered manner, which is to say, one end of the supporting part is exposed out of the glass part. The injection molding is performed to form a handheld mobile device casing that encapsulates the glass part and supporting part. With that molding method, the boundary of the sight window can be tightly coupled to the casing, without any offset or clearance. The glass sight window has high hardness and is wear resistant. The molding process is easy to operate, and the subsequent assembly process can be simplified.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

1. Field of the Invention

The present invention relates to a casing and a molding method, in particular to a handheld mobile device casing and a molding method of the handheld mobile device casing.

2. Description of Related Art

Including Information Disclosed Under 37 CFR 1.97 and 37 CFR 1.98.

The existing handheld mobile device casings can be manufactured into integral assemblies with a transparent sight window by means of a bi-color injection technique. FIG. 1 is a schematic structural diagram (1) of a handheld mobile device casing in the prior art. FIG. 2 is a sectional view in A-A direction of the handheld mobile device casing shown in FIG. 1. FIG. 3 is an enlarged view of the structure of part B in FIG. 2. As shown in FIGS. 1, 2, and 3, a transparent thermoplastic sight window 11 and a thermoplastic casing 12 are molded into an integral assembly. In that approach, though the boundary of the sight window can be jointed to the peripheral structure perfectly, and thereby an offset-free and clearance-free visual effect can be achieved. The sight window can only be made of thermoplastic material, in order to apply the integral molding process. Such a sight window has unsatisfactory hardness and transparency, is easy to wear out, and is not durable enough.

There is another sort of handheld mobile device casing in the market, on which a glass sight window is directly bonded. FIG. 4 is a schematic structural diagram (2) of a handheld mobile device casing in the prior art. FIG. 5 is a sectional view in C-C direction of the handheld mobile device casing shown in FIG. 4. FIG. 6 is an enlarged view of the structure of part D in FIG. 5. As shown in FIGS. 4, 5, and 6, a glass sight window 21 is directly bonded to a casing 23 by means of double-sided adhesive 22. Though such a sight window is clearer and more durable, some clearance and offset will be left after the sight window is assembled to the casing, resulting in a degraded visual effect.

### SUMMARY OF THE INVENTION

In view of the above drawback in the existing handheld mobile device casings, the present invention provides a handheld mobile device casing that is simple in structure, durable, and has an attractive appearance. The present invention also provides a molding method of the handheld mobile device casing.

The technical scheme for solving the technical problems described above in the present invention is as follows: a molding method for handheld mobile device casing, comprising the following steps:

step 101: manufacturing a glass part and a supporting part respectively, wherein, the glass part is used as a sight window on the handheld mobile device casing, and the supporting part is used to support the glass part;

step 102: placing the glass part on the supporting part in a staggered manner, which is to say, one end of the supporting part is exposed out of the glass part;

step 103: performing injection molding for the supporting part, with the glass part placed on the supporting part, to form a handheld mobile device casing that encapsulates the glass part and the supporting part, i.e., the handheld mobile device casing mentioned above.

The present invention has the following beneficial effects: the molding method of handheld mobile device casing in the present invention is simple, easy to operate, and low in cost. Since the glass part and supporting part are molded together with the casing into an integral piece by injection molding, the subsequent assembly process can be simplified, and the resulting handheld mobile device casing is low in cost. Moreover, the boundary of the glass sight window can be jointed to the casing perfectly, achieving an offset-free and clearance-free visual effect. Since the sight window is made of glass, it is durable, has satisfactory hardness and transparency, and outstanding mechanical properties.

On the basis of the technical scheme described above, the present invention can be further improved as follows:

Moreover, the glass part described in step 101 is manufactured in a way that the side walls are made into straight wall structures, which is to say, the side walls of the glass part are perpendicular to the top surface and bottom surface of the glass part.

Moreover, the glass part described in step 101 is manufactured in a way that the side walls are made into skirt structures, which comprises a first flat section, a second flat section, and a cambered section. One end of the second flat section is connected to the first flat section, and the other end of the second flat section is tangent to the cambered section. One end of the first flat section is connected to the second flat section, and the other end of the first flat section is connected to the bottom surface of the glass part. One end of the cambered second is tangent to the second flat section, and the other end of the cambered section is connected to the top surface of the glass part.

Moreover, the degree of inclination of the first flat section is 70°˜90°, and the length of the first flat section along the inclined direction is 0.3 mm˜0.8 mm. The degree of inclination of the second flat section is 10°˜25°, and the length of the second flat section along the inclined direction is 0.6 mm˜1 mm. The radius of the cambered section is 0.2 mm˜0.5 mm.

Moreover, if the side walls of the glass part are straight wall structures, in step 102, adhesive is applied on the glass part or supporting part first, and then the glass part is placed on the supporting part, so that the glass part is bonded to the supporting part.

Moreover, if the side walls of the glass part are skirt structures, in step 102, the glass part is directly placed on the supporting part.

The present invention further provides the following technical scheme to solve the above-mentioned technical problem: a handheld mobile device casing, comprising a casing, a supporting part, and a glass sight window, wherein, the casing encapsulates the supporting part and is fixed to the supporting part. The casing has an opening, the glass sight window is mounted on the supporting part through the opening of the casing, and the boundary of the glass sight window is tightly jointed to the casing. The shape of the glass sight window matches the shape of the opening of the casing.

Moreover, the handheld mobile device casing further comprises an adhesive layer, which is arranged between the glass sight window and the supporting part.

Moreover, if the side walls of the glass sight window are straight wall structures, the supporting part is a thermoplastic part or metal part. If the side walls of the glass sight window are skirt structures, the supporting part is a molded thermoplastic part or thermoplastic part, or a metal part.

Moreover, if the supporting part is a molded thermoplastic part, it is made of a mixture of polycarbonate and acrylonitrile-butadiene-polypropylene copolymer or mixture of polycarbonate and fiber glass, in thickness of 0.4 mm˜1.2 mm. If the supporting part is a thermoplastic part, it is made of polycarbonate, in thickness of 0.4 mm˜1.0 mm. If the supporting part is a metal part, it is made of stainless steel, in thickness of 0.3 mm˜1.0 mm.

### BRIEF DESCRIPTION OF THE DRAWINGS

FIG. 1 is a schematic view of a structural diagram (1) of a handheld mobile device casing in the prior art.

FIG. 2 is a sectional view in A-A direction of the handheld mobile device casing shown in FIG. 1.

FIG. 3 is an enlarged sectional view of the structure of part B in FIG. 2.

FIG. 4 is a schematic view of structural diagram (2) of a handheld mobile device casing in the prior art.

FIG. 5 is a sectional view in C-C direction of the handheld mobile device casing shown in FIG. 4.

FIG. 6 is an enlarged sectional view of the structure of part D in FIG. 5.

FIG. 7 is a flow diagram of the molding method of handheld mobile device casing in the present invention.

FIG. 8 is a schematic view of a structural diagram of a first embodiment of the glass part in the present invention.

FIG. 9 is a schematic view of a structural diagram of a second embodiment of the glass part in the present invention.

FIG. 10 is a schematic view of a structural diagram of a first embodiment of the handheld mobile device casing in the present invention.

FIG. 11 is a schematic view of a structural diagram of a second embodiment of the handheld mobile device casing in the present invention.

FIG. 12 is a schematic view of a structural diagram of a third embodiment of the handheld mobile device casing in the present invention.

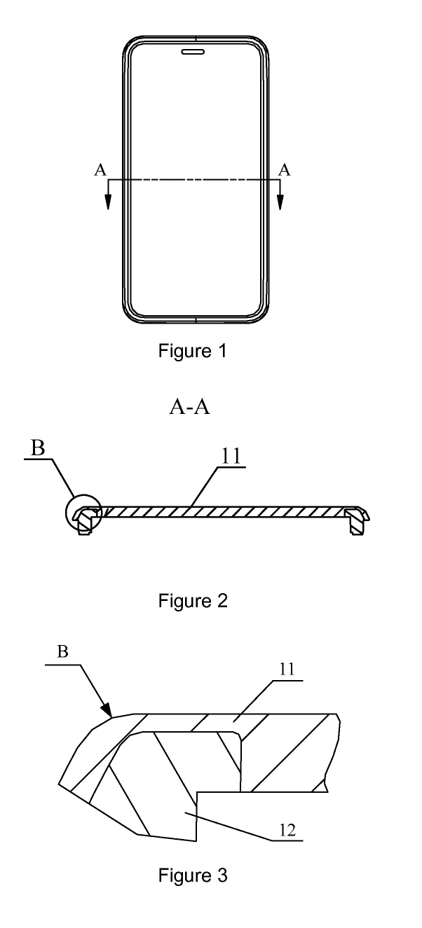

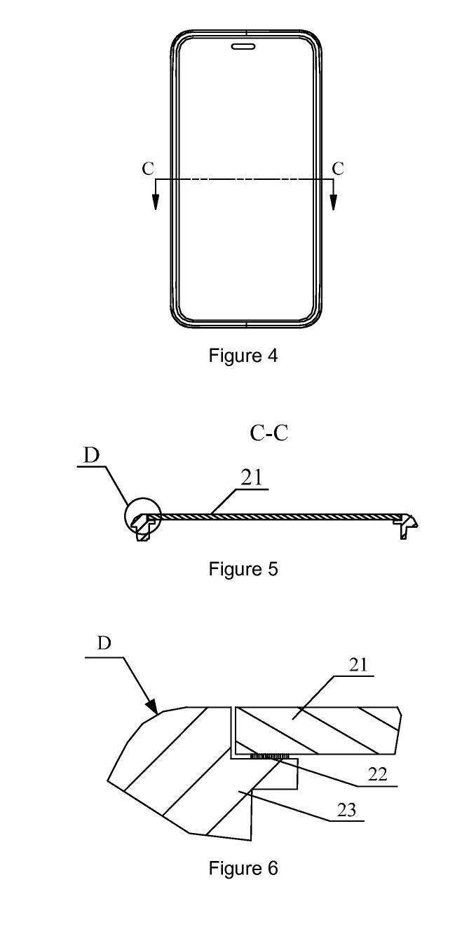

### DETAILED DESCRIPTION OF THE DRAWINGS

Hereunder, the principle and characteristics of the present invention will be detailed with reference to the accompanying drawings. However, it should be noted that the embodiments are provided only to interpret the present invention, and don't constitute any limitation to the scope of the present invention.

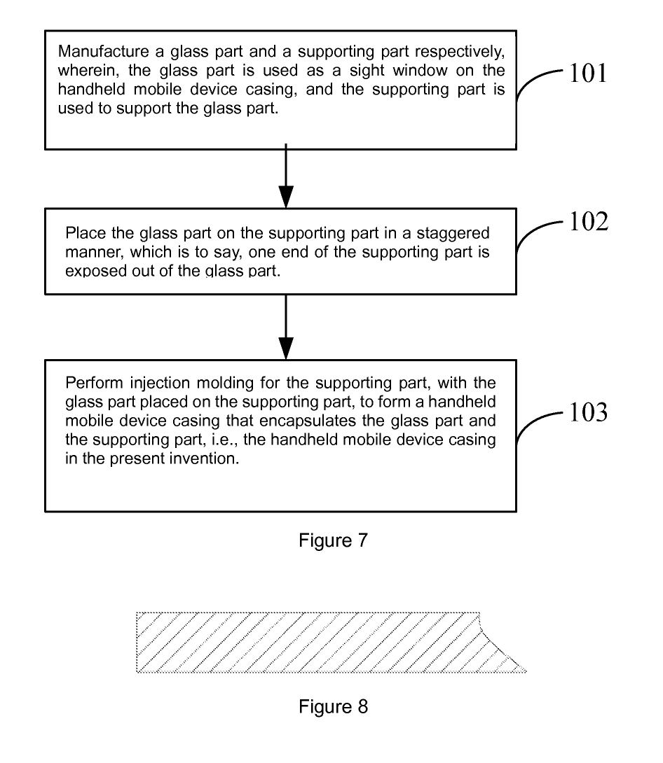

FIG. 7 is a flow diagram of the molding method of handheld mobile device casing in the present invention. As shown in FIG. 7, the molding method of handheld mobile device casing comprises the following steps:

Step 101: manufacturing a glass part and a supporting part respectively, wherein, the glass part is used as a sight window on the handheld mobile device casing, and the supporting part is used to support the glass part.

FIG. 8 is a schematic structural diagram of a first embodiment of the glass part in the present invention. In that step, the glass part is manufactured in a way that the side walls are made into straight wall structures, as shown in FIG. 8, which is to say, the side walls of the glass part are perpendicular to the top surface and bottom surface of the glass part.

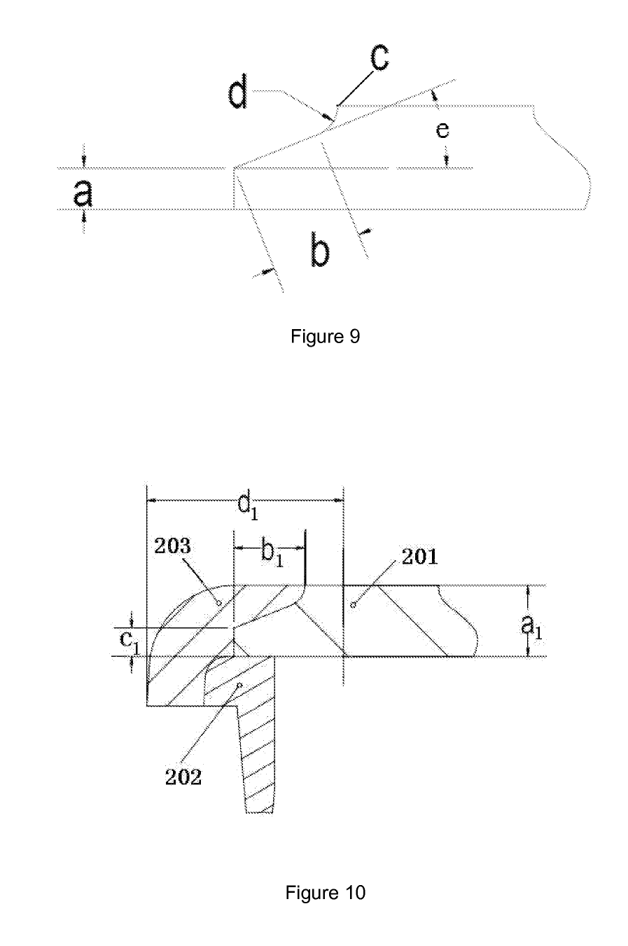

FIG. 9 is a schematic structural diagram of a second embodiment of the glass part in the present invention. In that step, the side walls of the glass part are made into skirt structures. As shown in FIG. 9, the side wall in skirt structure comprises a first flat section a, a second flat section b, and a cambered section c, wherein, one end of the second flat section b is connected to the first flat section a, and the other end of the second flat section b is tangent to the cambered section c. One end of the first flat section a is connected to the second flat section b, and the other end of the first flat section a is connected to the bottom surface of the glass part. One end of the cambered second c is tangent to the second flat section b, and the other end of the cambered section c is connected to the top surface of the glass part. The degree of inclination of the first flat section a is 70°˜90°, and the length of the first flat section a along the inclined direction is 0.4 mm˜0.8 mm. The degree of inclination e of the second flat section b is 15°˜25°, and the length of the second flat section b along the inclined direction is 0.6 mm˜1 mm. The radius d of the cambered section c is 0.2 mm˜0.5 mm. In this embodiment, the degree of inclination of the first flat section a is 90°, the degree of inclination of the second flat section b is 18°, and the radius d of the cambered section c is 0.3 mm.

Sequentially, the processing procedures of the glass part include: cutting of master plate, shaping, grinding, polishing, and chemical hardening. Through such a process, the glass part shown in FIGS. 8 and 9 is produced.

Step 102: placing the glass part on the supporting part in a staggered manner, which is to say, one end of the supporting part is exposed out of the glass part.

If the side walls of the glass part are straight wall structures, in that 102, adhesive is applied on the glass part or supporting part first, and then the glass part is placed on the supporting part, so that the glass part is bonded to the supporting part. The adhesive is 3M™2665 thermosetting adhesive or an equivalent product. Or, a double-sided adhesive layer is placed between the glass part and the supporting part, so that the glass part is bonded to the supporting part. Here, the glass part is fixed to the supporting part by means of adhesive or double-sided adhesive because the thickness of the glass part is too low, and therefore the glass part has to be manufactured in a way that the side walls are made into straight wall structures. If the glass part is not fixed to the supporting part by means of adhesive or double-sided adhesive, the glass part may fall off the surface of the supporting part if the handheld mobile device casing when the handheld mobile device casing suffers impact of external force, i.e., the glass part may fall off the handheld mobile device casing and therefore may be damaged.

If the side walls of the glass part are skirt structures, in that step, the glass part can be directly placed on the supporting part. In that case, the glass part can be made into a structure with skirts equivalent to a special protruding structure, i.e., a protruding structure formed by the first flat section and second flat section that have different degrees of inclination. That structure can be embedded firmly in the handheld mobile device casing, so that the glass part will not be separated from the surface of the supporting part easily even when the handheld mobile device casing suffers external force impact, which is to say, the glass part will fall off the handheld mobile device casing easily and therefore will not be damaged under external force impact.

The supporting part is mainly designed to support the glass part, and can be in any shape, as long as the supporting part protrudes out of the glass part partially when the glass part is placed on the supporting part, so that the supporting part and glass part can be bonded to the injection-molded part (i.e., the handheld mobile device casing) in the subsequent injection molding process.

Step 103: performing injection molding for the supporting part, with the glass part placed on the supporting part, to form a handheld mobile device casing that encapsulates the glass part and the supporting part, i.e., the handheld mobile device casing mentioned above.

The parameters required in the injection molding process in step 103 and the parameter values are shown in Table 1.

| Material code | | PC |
|---|---|---|
| Color | | Black |
| Cylinder | Jet nozzle | 315 |
| temperature | Section 1 | 305 |
| (° C.) | Section 2 | 290 |
| | Section 3 | 275 |
| Mold | Fixed side | 100 |
| temperature | Movable side | 100 |
| (° C.) | | |
| Speed and | Pressure 1 (bar)/speed 1 (mm/s)/ | 2000/95/17 |
| position | position 1 (mm) | |
| | Pressure 2 (bar)/speed 2 (mm/s)/ | 2000/85/15 |
| | position 2 (mm) | |
| Switching | Position (mm) | 5 |
| Holding | Holding 1 (bar)/time 1 (s) | 800/0.1 |
| Plasticizing | Back pressure 1 (bar)/revolution 1 | 10/120/60 |
| | (bar)/position 1 (mm) | |
| | Forward release withdraw (mm)/ | 0/4 |
| | backward release withdraw (mm) | |
| | Release withdraw time (s) | 35 |

| | |
|---|---|
| Cooling time (s) | 12 |
| Cycle time (s) | 36 |

FIG. 10 is a schematic structural diagram of a first embodiment of the handheld mobile device casing in the present invention. As shown in FIG. 10, in this embodiment, the cross sectional shape of the supporting part 202 is an inverted L shape, the dimensional of the glass sight window 201 is 0.7 mm˜1.5 mm, the dimension b1 of the contacting part between the casing 203 and the glass sight window 201 is 0.3 mm˜3 mm, the dimension c1 of the contacting part between the casing 203 and the glass sight window 201 is 0.3 mm˜1.2 mm, and the dimension d1 is greater than or equal to 3.2 mm.

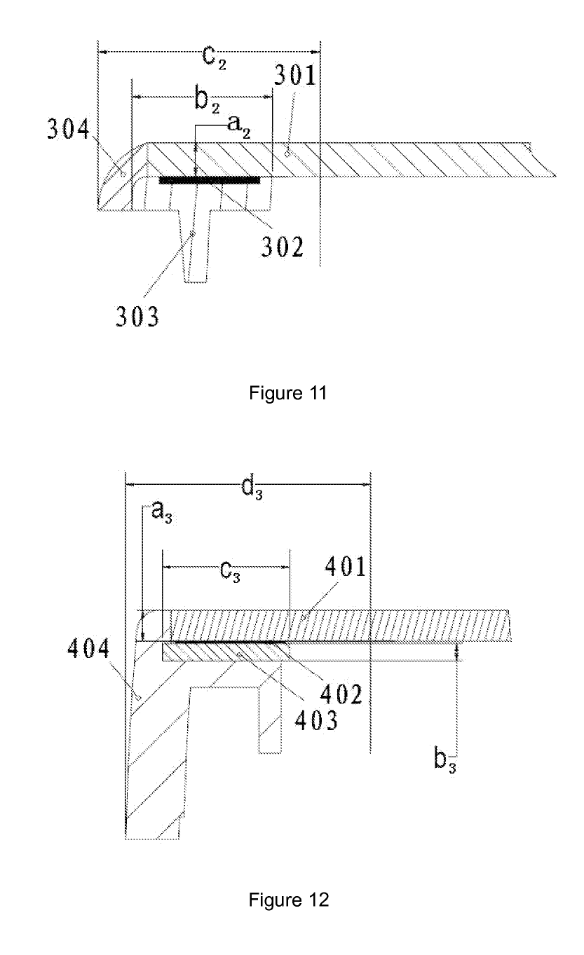

FIG. 11 is a schematic structural diagram of a second embodiment of the handheld mobile device casing in the present invention. As shown in FIG. 11, in this embodiment, the cross sectional shape of the supporting part 303 is a T shape. There is an adhesive layer 302 between the glass sight window 301 and the supporting part 303. The dimension a2 of the glass sight window 301 is 0.3 mm˜0.7 mm, the dimension b2 of the supporting part 303 is 1 mm˜3 mm, and the dimension c2 of the casing 304 and partial glass sight window 301 is greater than or equal to 5 mm.

FIG. 12 is a schematic structural diagram of a third embodiment of the handheld mobile device casing in the present invention. As shown in FIG. 12, in this embodiment, the supporting part 403 is a flat plate, there is an adhesive layer 402 between the glass sight window 401 and the supporting part 403. The dimension a3 of the glass sight window 401 is 0.3 mm˜0.7 mm, the dimension b3 of the supporting part 403 is greater than or equal to 0.3 mm, the dimension c3 of the supporting part 403 is 1.0 mm˜3.0 mm, and the dimension d3 of the casing 404 and partial glass sight window 401 is greater than or equal to 3.2 mm.

While the present invention is described above in some preferred embodiments, the present invention is not limited to those preferred embodiments. Any modification, equivalent replacement, and improvement made without departing from the spirit and principle of the present invention shall be deemed as falling into the protected domain of the present invention.

1. A molding method of a handheld mobile device casing, comprising the following steps:
manufacturing a glass part and a supporting part respectively, said glass part forming a sight window on the handheld mobile device casing, said supporting part supporting said glass part;
placing said glass part on said supporting part in a staggered manner, one end of the supporting part being exposed out of the glass part; and
performing injection molding for the supporting part, with the glass part placed on the supporting part, so as to form a handheld mobile device casing encapsulating the glass part and the supporting part.

2. The molding method of the handheld mobile device casing according to claim 1, wherein the step of manufacturing said glass part comprises making side walls of straight wall structures, said side walls of the glass part being perpendicular to a top surface and a bottom surface of the glass part.

3. The molding method of handheld mobile device casing according to claim 1, wherein the step of manufacturing the glass part comprises making side walls into skirt structures, said skirt structures being comprised of a first flat section, a second flat section, and a cambered section respectively, wherein one end of the second flat section is connected to the first flat section wherein an opposite end of the second flat section is tangent to the cambered section, wherein one end of the first flat section is connected to the second flat section, wherein an opposite end of the first flat section is connected to the bottom surface of the glass part, wherein one end of the cambered section is tangent to the second flat section, and wherein an opposite end of the cambered section is connected to the top surface of the glass part.

4. The molding method of handheld mobile device casing according to claim 3, wherein said first flat section has a degree of inclination of 70°˜90° and a length of 0.3 mm˜0.8 mm along an inclined direction, wherein said second flat section has a degree of inclination of 10°˜25° and a length of 0.6 mm˜1 mm along an inclined direction, and wherein said cambered section has a radius of 0.2 mm˜0.5 mm.

5. The molding method of handheld mobile device casing according to claim 2, wherein side walls of the glass part are straight wall structures, and wherein the step of placing the glass part further comprises applying adhesive, and then placing the glass part on the supporting part, so that the glass part is bonded to the supporting part.

6. The molding method of handheld mobile device casing according to claim 3, wherein side walls of the glass part are skirt structures, and wherein the step of placing the glass part further comprising directly placing the glass part on the supporting part.

7. A handheld mobile device casing, comprising:
a casing,
a supporting part, and
a glass sight window,
wherein said casing encapsulates the supporting part and is fixed to the supporting part, wherein said casing has an opening, wherein the glass sight window is mounted on the supporting part through the opening of the casing, and wherein a boundary of the glass sight window is tightly jointed to the casing, a shape of the glass sight window matching a shape of the opening of the casing.

8. The handheld mobile device casing according to claim 7, further comprising an adhesive layer, being arranged between the glass sight window and the supporting part.

9. The handheld mobile device casing according to claim 7, wherein side walls of the glass sight window are straight wall structures, and wherein the supporting part is a selected from a group consisting of a thermoplastic part and a metal part,
wherein side walls of the glass sight window are skirt structures, and wherein the supporting part is selected from a group consisting of a molded thermoplastic part, a thermoplastic part, and a metal part.

10. The handheld mobile device casing according to claim 9, wherein, the supporting part is a molded thermoplastic part, said molded thermoplastic part being comprised of a mixture, said mixture being selected from a group consisting of a mixture of polycarbonate and acrylonitrile-butadiene-phenethylene copolymer, and a mixture of polycarbonate and fiber glass, said molded thermoplastic part having thickness of 0.4 mm˜1.2 mm,
wherein said supporting part is a thermoplastic part comprised of polycarbonate, in thickness of 0.4 mm˜1.0 mm,
and wherein said supporting part is comprised of a metal part, said metal part being comprised of stainless steel, in thickness of 0.3 mm˜1.0 mm.
